(19) United States
(12) Patent Application Publication
(10) Pub. No.: US 2025/0216188 A1
(43) Pub. Date: Jul. 3, 2025

(54) CALIBRATION FOR IN-PLANE DISTORTION TOOL-TO-TOOL MATCHING

(71) Applicant: KLA Corporation, Milpitas, CA (US)

(72) Inventors: Wenjiang Guo, Singapore (SG); Chenkoon Toh, Singapore (SG); David Owen, Milpitas, CA (US)

(21) Appl. No.: 18/401,569

(22) Filed: Dec. 31, 2023

(51) Int. Cl. G01B 9/02055; G01B 11/24

(52) U.S. Cl. CPC G01B 9/02072; G01B 11/2441

(57) ABSTRACT

A shape map can be extracted for a workpiece, such as a semiconductor wafer. A calibration map of the workpiece can be extracted from this shape map to generate a calibrated shape map. In-plane distortion matching can be performed using the calibrated shape map. The in-plane distortion matching can be performed between two metrology tools.

### FIELD OF THE DISCLOSURE

This disclosure relates to workpiece metrology.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing workpieces, such as semiconductor wafers, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on workpieces, metrology processes are used to measure one or more characteristics of the workpieces that cannot be determined using existing inspection tools. Metrology processes can be used to measure one or more characteristics of workpieces such that the performance of a process can be determined from the one or more characteristics. For example, metrology processes can measure a dimension (e.g., line width, thickness, etc.) of features formed on the workpieces during the process. In addition, if the one or more characteristics of the workpieces are unacceptable (e.g., out of a predetermined range for the characteristic(s)), the measurements of the one or more characteristics of the workpieces may be used to alter one or more parameters of the process such that additional workpieces manufactured by the process have acceptable characteristic(s).

Interferometers are used in the semiconductor industry for metrology. Workpieces are held still during interferometry measurement. In most metrology tools, a pallet with three grippers is used to hold the workpiece. However, to hold the workpiece still, a certain amount of force is needed to be exerted by the grippers on the workpiece contact points, which will inevitably create some deformation or distortion on the workpiece shape. This distortion varies between tools or between pallets. Hence, workpiece shapes measured from different tools or different pallets will be largely affected by this gripper-induced distortion, and a mismatch may make a tool fail the inline monitoring requirements. Among many shape related metrics, in-plane distortion (IPD) is identified as one of the most effective inline monitoring indicators. Thus, the monitoring of IPD tool-to-tool matching is a key metrology criterion even though it is impacted largely by the gripper-induced distortion.

Generally, certain requirements are established for the flatness and thickness uniformity of the workpieces. However, chucking of workpieces with a workpiece shape (defined as the median surface of the workpiece in its free state obtained from the front and back surfaces of the wafer) and thickness variations results in elastic deformation that can cause IPD. IPD may lead to errors in downstream applications such as overlay errors in lithographic patterning or the like. Therefore, providing the ability to predict/estimate IPD due to wafer shape in the chucking process and to control the workpiece shape specification can improve the semiconductor manufacturing process.

Tool-to-tool matching and maintaining tool measurement consistency over time, over maintenance cycles, and over a wide range of measurement applications are challenges in the development of a metrology system that meets semiconductor manufacturer requirements. Process and yield control in both the research and development and manufacturing environments demands tool-to-tool consistency of measurement results on the order of the measurement repeatability. Thus, methods and systems for improved tool-to-tool matching and consistent measurement performance over a wide range of measurement applications are needed.

### BRIEF SUMMARY OF THE DISCLOSURE

A method is provided in a first embodiment. The method includes extracting, using a processor, a shape map of a workpiece. Using the processor, a calibration map of the workpiece is subtracted from the shape map to generate a calibrated shape map. Using the processor, in-plane distortion matching is determined using the calibrated shape map.

The method can further include acquiring images of the workpiece at a plurality of angles around the workpiece. The plurality of angles includes at least three angles. A first averaged shape map from the plurality of angles and a second shape map from a 0° acquisition angle can be determined using the processor. Using the processor, the second shape map is subtracted from the first averaged shape map to generate the calibration map. The plurality of angles may include twelve angles.

The workpiece may be a semiconductor wafer.

The method can further include associating the calibrated shape map with a pallet that is configured to hold the workpiece.

The in-plane distortion matching may be between two metrology tools. In an instance, the metrology tools are each an interferometer tool. The in-plane distortion matching also may be between two pallets. The pallets are each configured to hold the workpiece.

The second shape map can be averaged from a plurality of 0° acquisition angle shape maps.

A non-transitory computer readable medium storing a program can be configured to instruct a processor to execute the method of the first embodiment.

A system is provided in a second embodiment. The system includes an interferometer tool configured to obtain one or more measurements of a workpiece. The one or more measurements include one or more in-plane distortion measurements of the workpiece. A processor is in electronic communication with the interferometer tool. The processor is configured to: extract a shape map of a workpiece; subtract a calibration map of the workpiece from the shape map to generate a calibrated shape map; and determine in-plane distortion matching using the calibrated shape map.

The processor can be further configured to: receive images of the workpiece at a plurality of angles around the workpiece; determine a first averaged shape map from the plurality of angles; determine a second shape map from a 0° acquisition angle; and subtract the second shape map from the first averaged shape map to generate the calibration map. The plurality of angles includes at least three angles. In an instance, the plurality of angles includes twelve angles.

The workpiece may be a semiconductor wafer.

The processor can be further configured to associate the calibrated shape map with a pallet that is configured to hold the workpiece.

The second shape map can be averaged from a plurality of 0° acquisition angle shape maps.

The in-plane distortion matching may be between the interferometer tool and another interferometer tool. The in-plane distortion matching also may be between two pallets configured to hold the workpiece. One of the pallets is part of the interferometer tool.

### DESCRIPTION OF THE DRAWINGS

For a fuller understanding of the nature and objects of the disclosure, reference should be made to the following detailed description taken in conjunction with the accompanying drawings, in which:

FIG. 1 shows gripper induced distortion impacting shape mismatch between two tools;

FIG. 2 is a flowchart of an embodiment of a method in accordance with the present disclosure;

FIG. 3 shows an embodiment of a process of generating a calibration map in accordance with the present disclosure; and

FIG. 4 is an embodiment of a system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

The embodiments disclosed herein improve IPD tool-to-tool matching by obtaining a workpiece shape at multiple different angles. An averaged shape can be considered as the workpiece's true shape because the gripper-induced distortion has been minimized by multiple times at each rotation angle. Gripper-induced distortion from that metrology tool or pallet can then be calculated by offsetting the true shape from the shape that is acquired at a normal angle, which is the calibration file for that metrology tool or pallet. When subtracting the calibration file from subsequent measurements, the calibrated shape can be considered as “free” of gripper-induced distortion, which will minimize the mismatch when evaluating IPD tool-to-tool matching.

IPD is a shape-induced overlay metric and is identified as one of the largest and effective inline monitoring indicators. Thus, good IPD tool-to-tool matching is desired. The embodiments disclosed herein improve IPD tool-to-tool matching via offsetting with a calibration map. The calibration map can be obtained by rotating a workpiece at, for example, 12 degrees. The 0° shape map is subtracted from the average of shape maps generated from all the angles. The calibration map can then be associated with each pallet.

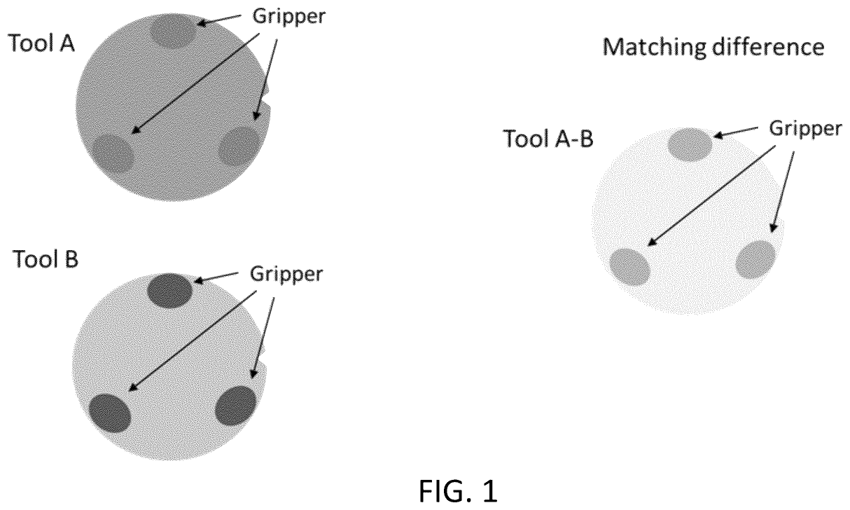

It was observed that the problematic regions for matching usually happen at pallet gripper regions as the contact points between pallet and wafer, as shown in FIG. 1. The pallet gripper-induced distortion is a primary reason for IPD tool-to-tool mismatch, and this distortion tends to depend more on the metrology tool or pallet than the workpiece. Thus, an angular calibration for each pallet or metrology tool is used to improve IPD tool-to-tool matching. After performing a calibration step where the shape of the calibration wafer is obtained at various angles, a calibration file can be calculated through an averaging and subtraction step, which is subsequently used of offset measurement data prior performing IPD matching.

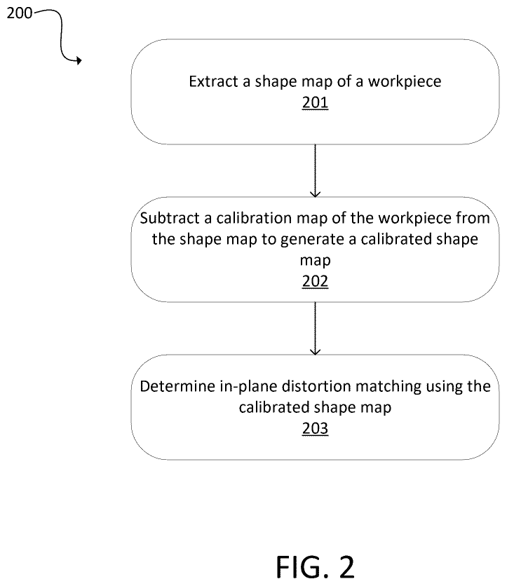

FIG. 2 is a flowchart of a method 200. One or more of the steps of the method 200 can be performed using a processor.

A shape map is extracted for a workpiece at 201, which can be a semiconductor wafer. In an instance, the shape map is extracted via calculating the median surface of the front and back plane of the workpiece, which can be measured using an interferometer. In another instance, the shape map can be extracted from a design file or specification for the workpiece.

For example, images of the workpiece can be acquired at a plurality of angles around the workpiece. The number of angles used can be at least three angles. Additional angles are possible. For example, twelve angles can be used. In an instance, the angles are acquired at 30° increments. Around the workpiece, images can be acquired at 0°, 30°, 60°, 90°, 120°, 150°, 180°, 210°, 240°, 270°, 300°, and 330°. In another instance, the images can be acquired at 0°, 120°, and 240° around the workpiece. The workpiece can be generally circular, so the images are taken around the circumference as measured from a starting or ending point.

The more different angles, the more accurate the result. However, this increases processing time. Fewer angles may result in less accurate results, though processing time is decreased. Fewer than three angles likely does not provide sufficient accuracy. More than twelve angles is possible.

The location of the 0° angle can vary with the workpiece. For example, the 0° angle can be the notch on a workpiece or the edge of the workpiece opposite the notch. For most workpieces, the location of the 0° does not affect results.

Based on the plurality of angles, a first averaged shape map can be determined. This can be referred to as a Shape_{all angles}. Each of the shape maps taken at a different angle can be averaged. A second shape map can be determined from the 0° acquisition angle, which can be referred to as Shape_{0°}. For example, a user can collect multiple maps at the 0° acquisition angle and average these maps to generate the second shape map. A user also can collect a single map at the 0° acquisition angle as the second shape map, which would not be averaged. The 0° acquisition angle used for the second shape map can be part of the other maps used herein or can be a separate map.

The second shape map can be subtracted from the first averaged shape map, such as using image subtraction. This generates a calibration map. The calibration map can be saved to memory after it is generated and can be used for later in-plane distortion matching. The calibration map may be periodically generated for a specific pallet or specific tool. For example, this step may be performed every few months or when a new pallet is installed on a tool.

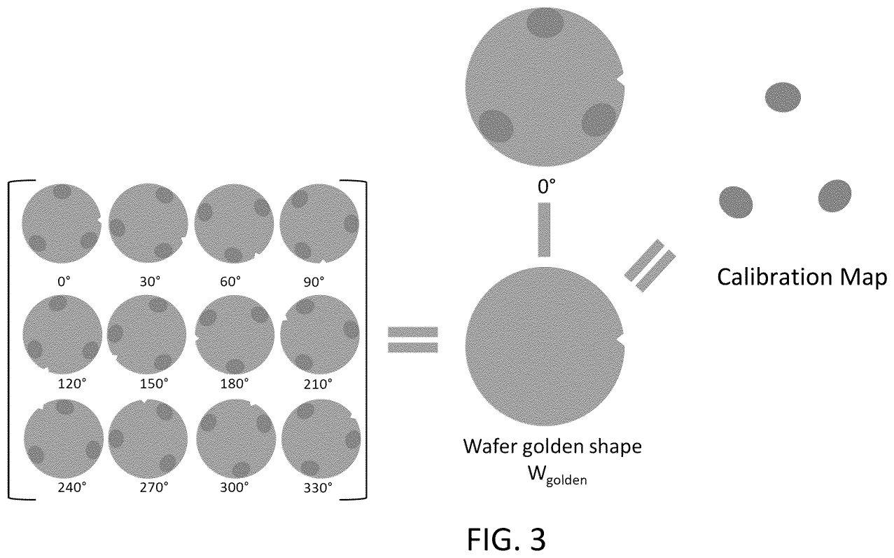

FIG. 3 shows an embodiment of a process of generating a calibration map. As shown in the array, twelve images of a workpiece are acquired. The 0° image is subtracted to generate a calibration map. The wafer golden shape in FIG. 3 is the averaged shape map of all acquisition angles. The calibration map can be obtained via subtracting the wafer golden shape from 0° shape map.

Turning back to FIG. 2, a calibration map of the workpiece is subtracted from the shape map to generate a calibrated shape map at 202, such as using image subtraction. The calibration map includes pallet-specific or tool-specific shape distortions. The calibrated shape map can be associated with a pallet that is configured to hold the workpiece.

In-plane distortion matching is determined using the calibrated shape map at 203. In an embodiment, in-plane distortion matching can be between two metrology tools. For example, two interferometer tools can be subject to in-plane distortion matching. In another embodiment, in-plane distortion matching can be between two pallets that are each configured to hold the workpiece or different workpieces. In-plane distortion calculation is a standard practice as specified in a SEMI standard. In-plane distortion matching is to derive the differences in the in-plane distortion determined from the same workpiece when measured in different processes and/or tools.

In an embodiment, in-plane distortion matching is performed by acquiring a wafer shape map. The acquired shape map can be calibrated by subtracting the calibrated shape map for the tool or pallet. The resulting shape map after the calibration can then be used for in-plane distortion matching.

The interferometer tool may include any interferometer tool known in the art. For example, the interferometer tool may be configured to measure any number of spatial characteristics of the workpiece including, but not limited to, flatness, shape variation, thickness variation, and/or any other spatial parameter variations of the workpiece. The spatial characteristics of the workpiece may be related to the wafer geometry of the workpiece, and may additionally be represented by out-of-plane distortions (OPD). A description of the use of wafer geometry metrics for overlay and semiconductor process control is described in U.S. Pat. No. 9,354,526, which is incorporated herein in its entirety. Additionally, a description of the use of wafer geometry metrics for overlay and semiconductor process control is described in U.S. Patent Publication No. 2016/0372353, which is incorporated herein in its entirety.

In another example, the interferometer tool may include, but is not limited to, a dual wavelength dual interferometer. For instance, the dual wavelength dual interferometer may include, but is not limited to, a dual wavelength dual Fizeau interferometer (DWDFI). In another example, the interferometer tool may be adapted to perform patterned wafer geometry (PWG) measurements on the workpiece, whereby the dynamic range of the sample slope (e.g., wafer slope) measured by the interferometer tool is extended by stitching measurement results of different regions of the workpiece together.

A description of a dual wavelength dual interferometer is described in U.S. Pat. No. 6,847,458, which is incorporated herein by reference in its entirety. Additionally, a description of a dual wavelength dual interferometer is described in U.S. Pat. No. 8,068,234, which is incorporated herein by reference in its entirety.

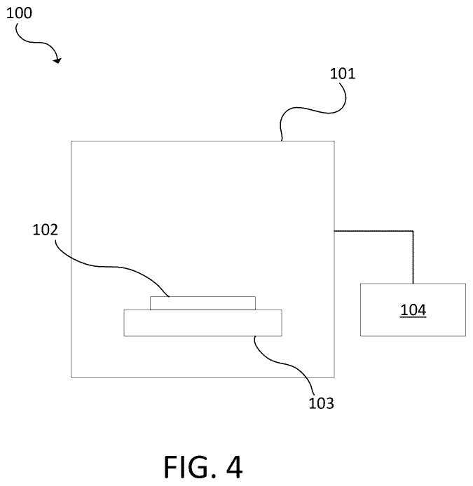

FIG. 4 is an embodiment of a system 100. In the system 100, the interferometer tool 101 includes a workpiece 102 (e.g., a semiconductor wafer) on a pallet 103 or other stage or platen. A processor 104 is in electronic communication with the interferometer tool 101. The interferometer tool 101 can include measurement systems as described elsewhere herein.

While disclosed with in-plane distortion matching, other shape-related metrics can benefit from the embodiments disclosed herein. For example, bow or warp of a workpiece can benefit from the embodiments disclosed herein.

As used herein, the term “workpiece” generally refers to wafers formed of a semiconductor or non-semiconductor material (e.g., a semiconductor wafer). Examples of such a semiconductor or non-semiconductor material include, but are not limited to, monocrystalline silicon, gallium nitride, gallium arsenide, indium phosphide, sapphire, and glass. Such wafers may be commonly found and/or processed in semiconductor fabrication facilities.

A workpiece may include one or more layers formed upon it. For example, such layers may include, but are not limited to, a photoresist, a dielectric material, a conductive material, and a semiconductive material. Many different types of such layers are known in the art, and the term workpiece as used herein is intended to encompass a workpiece including all types of such layers.

One or more layers formed on a workpiece may be patterned or unpatterned. For example, a workpiece may include a plurality of dies, each having repeatable patterned features or periodic structures. Formation and processing of such layers of material may ultimately result in completed devices. Many different types of devices may be formed on a workpiece, and the term workpiece as used herein is intended to encompass a workpiece on which any type of device known in the art is being fabricated.

Other types of workpiece also may be used. For example, the workpiece may be used to manufacture LEDs, solar cells, magnetic discs, flat panels, or polished plates. Defects on other objects also may be classified using techniques and systems disclosed herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
extracting, using a processor, a shape map of a workpiece;
subtracting, using the processor, a calibration map of the workpiece from the shape map to generate a calibrated shape map; and
determining, using the processor, in-plane distortion matching using the calibrated shape map.

2. The method of claim 1, further comprising:
acquiring images of the workpiece at a plurality of angles around the workpiece, wherein the plurality of angles includes at least three angles;
determining, using the processor, a first averaged shape map from the plurality of angles;
determining, using the processor, a second shape map from a 0° acquisition angle; and
subtracting, using the processor, the second shape map from the first averaged shape map to generate the calibration map.

3. The method of claim 2, wherein the plurality of angles includes twelve angles.

4. The method of claim 1, wherein the workpiece is a semiconductor wafer.

5. The method of claim 1, further comprising associating the calibrated shape map with a pallet that is configured to hold the workpiece.

6. The method of claim 1, wherein the in-plane distortion matching is between two metrology tools.

7. The method of claim 6, wherein the metrology tools are each an interferometer tool.

8. The method of claim 1, wherein the in-plane distortion matching is between two pallets, wherein the pallets are each configured to hold the workpiece.

9. The method of claim 1, wherein the second shape map is averaged from a plurality of 0° acquisition angle shape maps.

10. A non-transitory computer readable medium storing a program configured to instruct a processor to execute the method of claim 1.

11. A system comprising:
an interferometer tool configured to obtain one or more measurements of a workpiece, wherein the one or more measurements include one or more in-plane distortion measurements of the workpiece; and
a processor in electronic communication with the interferometer tool, wherein the processor is configured to:
extract a shape map of a workpiece;
subtract a calibration map of the workpiece from the shape map to generate a calibrated shape map; and
determine in-plane distortion matching using the calibrated shape map.

12. The system of claim 11, wherein the processor is further configured to:
receive images of the workpiece at a plurality of angles around the workpiece, wherein the plurality of angles includes at least three angles;
determine a first averaged shape map from the plurality of angles;
determine a second shape map from a 0° acquisition angle; and
subtract the second shape map from the first averaged shape map to generate the calibration map.

13. The system of claim 12, wherein the plurality of angles includes twelve angles.

14. The system of claim 11, wherein the workpiece is a semiconductor wafer.

15. The system of claim 11, wherein the processor is further configured to associate the calibrated shape map with a pallet that is configured to hold the workpiece.

16. The system of claim 11, wherein the in-plane distortion matching is between the interferometer tool and another interferometer tool.

17. The system of claim 11, wherein the in-plane distortion matching is between two pallets configured to hold the workpiece, wherein one of the pallets is part of the interferometer tool.

18. The system of claim 11, wherein the second shape map is averaged from a plurality of 0° acquisition angle shape maps.
